(19) United States
(12) Patent Application Publication
(10) Pub. No.: US 2026/0245828 A1
(43) Pub. Date: Aug. 20, 2026

(54) Electron Beam Application Device

(71) Applicant: Hitachi High-Tech Corporation, Minato-ku, Tokyo (JP)

(72) Inventors: Takashi OHSHIMA, Tokyo (JP); Hideo MORISHITA, Tokyo (JP); Shinichi MATSUBARA, Tokyo (JP); Daichi TAKANE, Tokyo (JP); Yoichi OSE, Tokyo (JP); Toshie YAGUCHI, Tokyo (JP)

(21) Appl. No.: 19/160,497

(22) PCT Filed: Jun. 23, 2023
(86) PCT No.: PCT/JP2023/023303

§ 371 Date: Aug. 28, 2025

(51) Int. Cl. H01J 37/244; H01J 37/073

(52) U.S. Cl. CPC H01J 37/244; H01J 37/073; H01J 2237/06333

(57) ABSTRACT

An electron beam application device according to the present invention is characterized by comprising: a photocathode 1 provided with a photoelectric film 10; a cathode heater 2 for heating the photocathode 1; an atomic hydrogen generating means 4 for generating atomic hydrogen by dissociating a hydrogen molecule; control means 7, 8 for controlling the surface cleaning of the surface of the photoelectric film 10; and a measuring means 18 for measuring the probe value of an electron beam probe 27 emitted from the photocathode 1. The present invention is further characterized in that, when the probe value measured by the measuring means 18 is lower than a predetermined value, the control means 7, 8 determine a surface cleaning condition of the photoelectric film 10, control the cathode heater 2 and the atomic hydrogen generating means 4 under the determined surface cleaning condition, and perform the surface cleaning of the surface of the photoelectric film 10.

### TECHNICAL FIELD

The present invention relates to an electron beam application device such as an electron microscope.

### BACKGROUND ART

In a high-resolution electron microscope, an electron source that has a high brightness and emits an electron beam with a narrow energy width, that is a monochromatic electron source, is essential. A photoexcitation electron source utilizing negative electron affinity (NEA) has characteristics of an extremely narrow energy width, monochromaticity that surpasses that of high-performance electron sources and high brightness. In addition, a short-pulse electron beam can be easily obtained by pulsing excitation light, which is also useful for measurement of time resolution.

In this photoexcitation electron gun, a surface of a photocathode that emits an electron beam is GaAs, and a low work function surface is created by Cs and oxygen adsorption on a GaAs photocathode surface by a process referred to as NEA activation (surface activation) of the surface. In an actual device, a surface cleaning process of removing oxides and carbides on a surface formed by gas adsorption in an initial state immediately after insertion into an electron gun of a photocathode or during operation in the electron gun is essential, and as disclosed in PTL 1, it is effective to heat the photocathode and irradiate the surface with atomic hydrogen obtained by dissociation of hydrogen molecules. To introduce hydrogen for this purpose, as shown in PTL 1, hydrogen gas in a hydrogen cylinder is introduced by manually operating a variable leak valve reducing a pressure.

On the other hand, it is important to keep a surface state of a needle shaped metal cathode, that is, a field emission (field emission) electron source or a Schottky emission (SE) electron source, which is used in a high brightness electron gun in the related art constant for stable operation, and for this reason, an ultra-high vacuum environment is formed in the electron gun. However, gas emission due to electron bombardment and gas inflow from a sample chamber side occur, and in particular, when carbon atoms are adsorbed, carbides are formed with a material such as W constituting the electron source and cannot be easily removed, resulting in a decrease in probe current and noise increase.

PTL 2 discloses that adsorbed carbons on a surface of a needle shaped electron source is reduced and removed by atomic hydrogen irradiation and discloses, as a method of introducing hydrogen, a method of generating hydrogen by heating a hydrogen storage alloy and a method of placing a hydrogen permeable film such as Pd between a container containing hydrogen and a vacuum chamber and heating the permeable film.

### CITATION LIST

### Patent Literature

PTL 1: JP2002-313273A

PTL 2: JP2007-172862A

### SUMMARY OF INVENTION

### Technical Problem

In a photoexcitation electron gun in the related art, since the surface cleaning process of the photocathode is manually performed, the activation process requires a long time of 1 hour or more, and further, there is a problem that a skill of a person who operates the variable leak valve is required, and there is a problem that usability for a user of an electron beam application device is poor. Further, in the electron gun using the needle shaped metal cathode in the related art, it is necessary to manually start the process in order to remove contamination due to the carbons or the like on the surface of the photocathode, and there is a limit to a continuous time in which the current can be observed in a stable state with a high brightness.

### Solution to Problem

An electron beam application device according to an embodiment of invention includes: a photocathode including a photoelectric film; a cathode heater configured to heat the photocathode; an atomic hydrogen generating unit configured to perform dissociation of hydrogen molecules to generate atomic hydrogen; a control unit configured to control surface cleaning of a surface of the photoelectric film; and a measurement unit configured to measure a value of probe of an electron beam probe emitted from the photocathode. When the value of probe measured by the measurement unit falls below a predetermined value, the control unit determines a surface cleaning condition of the photoelectric film, and controls the cathode heater and the atomic hydrogen generating unit under the determined surface cleaning condition to perform the surface cleaning on the surface of the photoelectric film.

### Advantageous Effects of Invention

According to the invention, since the surface cleaning of the photocathode or a needle shaped cathode is automatically performed in a short time with good reproducibility and without requiring skill, an electron gun capable of obtaining a stable probe current for a long time can be formed, and an electron beam application device with good usability can be obtained.

### BRIEF DESCRIPTION OF DRAWINGS

FIG. 1A is a schematic diagram of an electron beam application device using a photoexcitation electron gun according to Embodiment 1 of the invention.

FIG. 1B is a time lapse diagram of each component operation during surface cleaning according to Embodiment 1 of the invention.

FIG. 2A is a flowchart of automatic surface cleaning according to Embodiment 1 of the invention.

FIG. 2B is a history diagram of a value of probe current (Ip) according to Embodiment 1 of the invention.

FIG. 3 is a flowchart of operations of the electron beam application device using the photoexcitation electron gun according to Embodiment 1 of the invention.

FIG. 4A is an example of a hydrogen generating unit according to Embodiment 1 of the invention.

FIG. 4B is an example of the hydrogen generating unit according to Embodiment 1 of the invention.

FIG. 4C is an example of the hydrogen generating unit according to Embodiment 1 of the invention.

FIG. 5 is a schematic diagram of an electron beam application device using a needle shaped electron source according to Embodiment 2 of the invention.

FIG. 6 is a flowchart of operations of the electron beam application device using the needle shaped electron source according to Embodiment 2 of the invention.

FIG. 7 is a schematic diagram of an electron beam application device using a needle shaped electron source according to Embodiment 3 of the invention.

FIG. 8 is an example of a hydrogen generating unit according to Embodiments 1 to 3 of the invention.

### DESCRIPTION OF EMBODIMENTS

Hereinafter, embodiments of the invention will be described with reference to the drawings. In the drawings, the same components are denoted by the same reference signs, and detailed descriptions of redundant parts are omitted.

### Embodiment 1

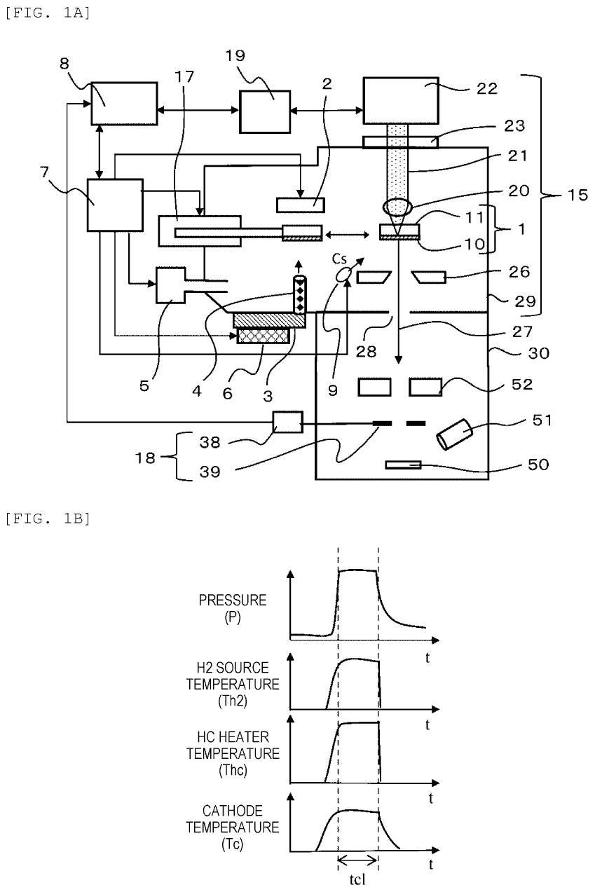

FIG. 1A is a schematic diagram of an electron beam application device using a photoexcitation electron gun according to Embodiment 1 of the invention. A photocathode 1 is a transmissive photocathode having a structure in which a photoelectric film 10 is provided on a surface of a transparent substrate 11 and having an electron beam emitting surface and an excitation light incident surface facing each other. The photocathode 1 can take two positions including an electron gun position on a right side and a surface cleaning position on a left side in FIG. 1A due to a linear motion feedthrough 17. The photoelectric film 10 is made of a material mainly including single crystal GaAs as described in PTL 1, and is a monochromatic electron beam emission source having a high brightness and uniform energy utilizing negative electron affinity (NEA) by performing a low work function on a surface and irradiating the surface with excitation light from a back surface.

When the photocathode 1 is at the electron gun position, excitation light 21 generated from a laser light source 22 in response to an instruction from an electron gun controller 19 is transmitted through a window 23 in an upper portion of a vacuum chamber 29, emitted to a small region due to a condensing lens 20 on the photoelectric film 10 whose surface on which the low work function is performed using Cs and oxygen, and as a result, emitted electrons are accelerated between the photocathode 1 and an extraction electrode 26, become an electron beam probe 27, pass through an aperture 28 from an electron gun 15, and enter an electron optics column 30 to be used as a microscope.

In the electron optics column 30, a sample 50 to be measured, a secondary electron detector 51, and an electron optics part 52 are provided. The electron optics part 52 controls the electron beam probe 27 including an electron lens, a deflector, and the like. The secondary electron detector 51, the electron optics part 52, the sample 50, which are elements in the electron optics column 30, and the electron gun controller 19 controlled by a system control device 8 function as an electron microscope for observing a microstructure of a surface of the sample 50 by the electron beam probe 27. The electron optics column 30 is typically used as a scanning electron microscope (SEM), a transmission electron microscope (TEM), or the like.

Energy of the electron beam probe 27 is determined by a potential of the photocathode 1. The photocathode 1 has an electrical contact with a cathode contact (not shown), and an acceleration voltage (V0) is applied from an external power supply (not shown) in response to an instruction from the electron gun controller 19. The energy of the electron beam probe 27 is determined by the acceleration voltage (V0). An emission current emitted from the photocathode 1 is monitored on a power supply side.

In the electron optics column 30, a probe current measuring unit 18 is disposed to monitor a value of probe current (Ip) of the electron beam probe 27 and communicate the value with the system control device 8. The probe current measuring unit 18 includes, for example, an aperture 39 and a current detector 38, and measures a current generated by electrons with which the aperture 39 is irradiated with a portion of the electron beam probe 27 extending from a center of a trajectory.

The low work function of the surface of the photoelectric film 10 is performed by vapor deposition of Cs by energization and heating of a Cs source 9 and introduction of an oxygen gas from an oxygen generating unit 5, which is referred to as a surface activation process. This control is automatically performed in response to an electric signal from a surface controller 7.

Here, increasing a brightness of the electron beam probe 27 is highly important since this increase leads to increasing a resolution of the electron microscope and shortening an observation time, and for this purpose, it is essential to make the surface of the photoelectric film 10 before surface activation a clean GaAs surface without oxides or carbides. In the invention, the photocathode 1 is placed at the surface cleaning position by the linear motion feedthrough 17, and removal of oxides and carbides by atomic hydrogen is automated. A configuration for the surface cleaning includes a cathode heater 2, an atomic hydrogen generator 4, a hydrogen generating unit 3, and a heating element (hydrogen heater) 6 in FIG. 1A, and these components operate in response to the electric signal from the surface controller 7.

FIG. 1B is a time lapse diagram of each component operation during the surface cleaning according to Embodiment 1 of the invention. The cathode heater 2 is energized and heated to heat a temperature (Tc) of the photocathode 1 from 400° C. to 500° C. The hydrogen generating unit 3 generates hydrogen by heating, and is heated to an H2 source temperature (Th2) by the heating element (hydrogen heater) 6 so as to obtain a desired pressure. As a result, a gas pressure (P) in the electron gun increases. At the same time, a W filament (hydrogen cracking (HC) heater) of the atomic hydrogen generator 4 is energized and heated to an HC heater temperature (Thc) for dissociation of hydrogen molecules and generation of highly reactive atomic hydrogen. The HC heater temperature is selected from 1800° C. to 2000° C. This state is automatically maintained for a determined surface cleaning time (tcl), and then each current value is stopped and both the temperature and the pressure return to original states thereof.

These surface cleaning conditions are automatically set by the surface controller 7 and the system control device 8. In the device in the related art, since this process is performed manually, temperature raising processes of the respective heaters cannot be performed at the same time and are sequentially performed, and thus a long time is required, but in the invention, since the processes can be performed at the same time, there is an advantage that a process time is short.

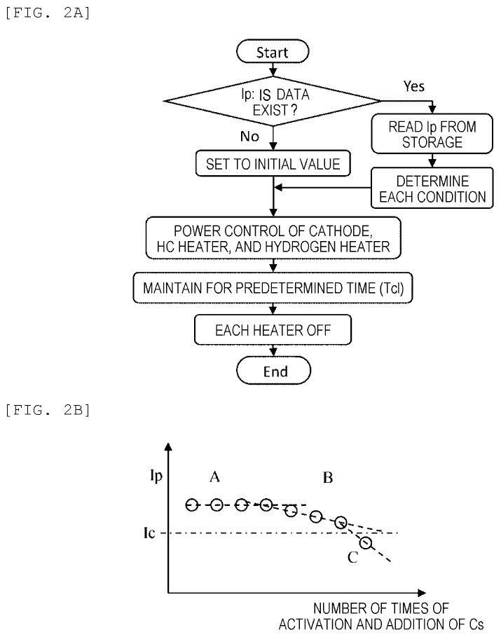

FIG. 2A is a flowchart of the automatic surface cleaning according to Embodiment 1 of the invention. This process is mainly performed in response to the signal from the surface controller 7. First, since the conditions differ depending on a history of the surface of the photocathode 1, in a case where there is a value of probe current (Ip) measured under standard conditions when the emission current increases due to the activation or the addition of Cs, the surface cleaning conditions are determined by a history of the value of probe current (Ip). The history of the value of probe current (Ip) is a record of the value of probe current (Ip) after the activation or the addition of Cs, and is stored in a storage of the system control device 8 in the present embodiment. Since the value of probe current (Ip) varies depending on the acceleration voltage (V0) and an intensity of the excitation light 21, the determination is made by measuring a current value at a constant acceleration and a constant excitation light intensity, that is, under the standard conditions. Actually, even if the acceleration voltage (V0) and the intensity of the excitation light 21 are changed, the value of probe current (Ip) measured under those conditions may be converted into that at the acceleration voltage and the intensity of the excitation light under the standard conditions and used. Alternatively, when the conditions are stable, the conversion may be performed from a value of the emission current from the photocathode 1. When the photocathode 1 is new and there is no measured value of probe current (Ip), the surface cleaning condition is set to an initial value.

Next, power of the cathode heater 2, the HC heater (the W filament of the atomic hydrogen generator 4), and the heating element (the hydrogen heater) 6 is controlled to achieve the set surface cleaning conditions, which are maintained for the set predetermined time (tcl), after which the power to each heater is stopped to end the process.

The surface cleaning conditions are determined as follows. In a case of the new photocathode 1 provided with a protective film on the surface formed by a crystal growth device, a clean surface is obtained by light surface cleaning. The surface cleaning conditions in this case are, for example, [Condition 1] including a hydrogen pressure (P) of 1×10\hat{ }−4 Pa, the HC heater temperature (Thc) of 1800° C., the cathode temperature (Tc) of 400° C., and the surface cleaning time (tcl) of 10 minutes to 20 minutes.

FIG. 2B is a history diagram of the value of probe current (Ip) according to Embodiment 1 of the invention. After the photocathode 1 is renewed, if contamination on the surface of the photoelectric film 10 is very small, the value of probe current (Ip) hardly changes by performing the activation or the addition of Cs. This region is indicated by A in FIG. 2B. When the surface of the photoelectric film 10 is slightly contaminated with oxides or carbides, the value of probe current (Ip) gradually decreases even if the activation or the addition of Cs is performed. This region is indicated by B in FIG. 2B. Further, when a sample containing a large amount of gas is observed in the electron optics column 30, the value of probe current (Ip) significantly decreases. This region is indicated by C in FIG. 2B. When the value of probe current (Ip) falls below a predetermined value (Ic), it is determined that the surface cleaning is required.

The surface cleaning conditions when the surface of the photoelectric film 10 is gradually contaminated and the value of probe current (Ip) falls below the predetermined value (Ic) are, for example, [Condition 2] including the hydrogen pressure (P) of 2×10\hat{ }−4 Pa, the HC heater temperature (Thc) of 1900° C., the cathode temperature (Tc) of 400° C., and the surface cleaning time (tcl) of 20 minutes. Further, when a decrease rate of the value of probe current (Ip) is large due to adsorption of dense oxygen gas on the surface of the photoelectric film 10 or the like, as stronger surface cleaning conditions, for example, [Condition 3] including the hydrogen pressure (P) of 2×10\hat{ }−4 Pa, the HC heater temperature (Thc) of 2000° C., the cathode temperature (Tc) of 500° C., and the surface cleaning time (tcl) of 20 minutes to 30 minutes is selected.

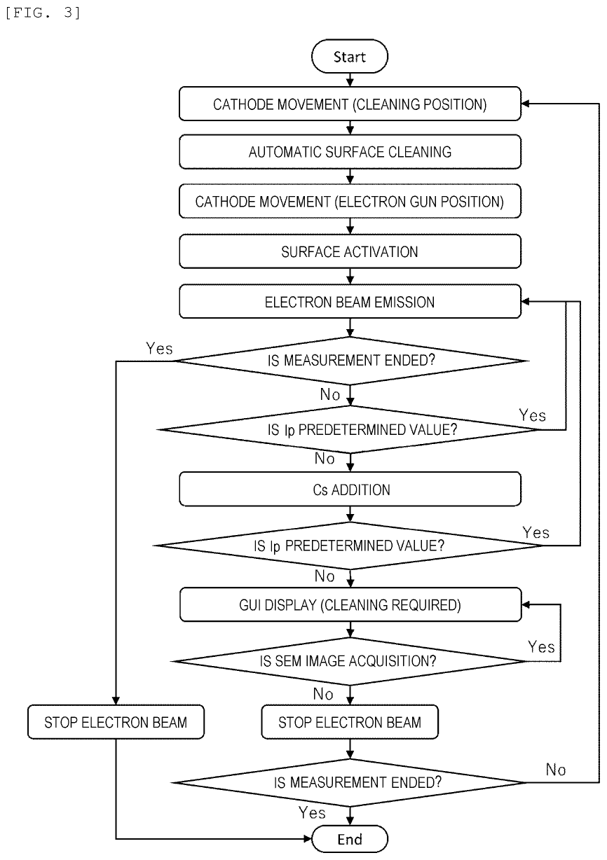

FIG. 3 is a flowchart of operations of the electron beam application device using the photoexcitation electron gun according to Embodiment 1 of the invention. First, the photocathode 1 is moved to the surface cleaning position. This moving is performed by applying an electric signal to motive power of the linear motion feedthrough 17 from the surface controller 7. Next, an automatic surface cleaning process of a flow shown in FIG. 2A is performed. When the photocathode 1 is new, first, the surface of the photoelectric film 10 is subjected to the surface cleaning under [Condition 1] described above. Next, the photocathode 1 is moved to the electron gun position by the linear motion feedthrough 17, and the surface of the photoelectric film 10 is subjected to the surface activation using Cs and oxygen. The electron beam emission is performed by irradiating the photocathode 1 with the excitation light 21. Thereafter, the predetermined acceleration voltage (V0) is applied to the photocathode 1 to emit an electron beam, thereby generating the electron beam probe 27. The probe current measuring unit 18 of the electron optics column 30 measures the value of probe current (Ip) whenever necessary or continuously, and if the value of probe current is equal to or greater than a predetermined value, the electron beam emission is continued and sample observation or the like is performed.

When the measurement is ended in the electron optics column 30, the electron beam is stopped and ended. When the value of probe current (Ip) decreases while the measurement is continued, the Cs source 9 is energized to add Cs. Accordingly, when the value of probe current (Ip) is recovered to the predetermined value or more, the electron beam emission is continued. When the value of probe current (Ip) does not reach the predetermined value, the surface cleaning is required, and in this case, the electron emission is required to be interrupted, and thus a display of the electron beam application device displays, by GUI display, that the surface cleaning (cleaning) is required. When an image is being acquired, only the image is continuously displayed. After the image acquisition is ended, the electron beam is stopped, and when the measurement is not ended, the photocathode 1 is moved to the surface cleaning position to perform the automatic surface cleaning.

In this case, the surface controller 7 calls data on the history of the value of probe current (Ip) from the storage of the system control device 8 as shown in FIG. 2A, and selects [Condition 1], [Condition 2], [Condition 3] or intermediate conditions therebetween as described above with reference to a reduction pattern as shown in FIG. 2B to perform the automatic surface cleaning. This selection may be performed by the system control device 8 in terms of the configuration of the system, and the result may be communicated to the surface controller 7, with the same effect being obtained.

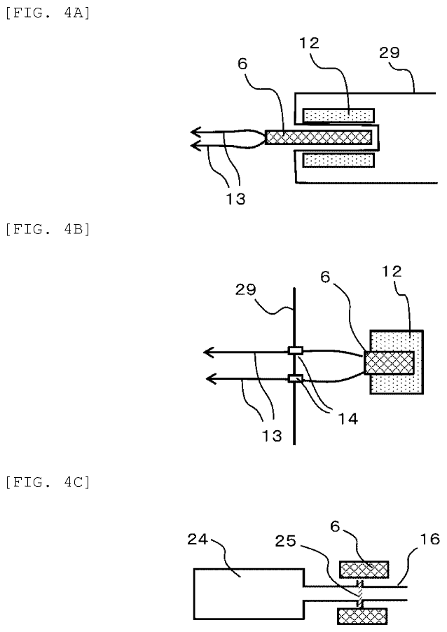

FIG. 4A shows an example of the hydrogen generating unit 3. A cylindrical hydrogen storage alloy 12 having a hole opened at a center is provided as the hydrogen generating unit 3 in vacuum in which the electron gun 15 is provided in the vacuum chamber 29. The heating element (hydrogen heater) 6 is inserted into the hole of the hydrogen storage alloy 12 from an atmospheric side outside the vacuum chamber 29, and an interconnect 13 of the heating element (hydrogen heater) 6 is energized to increase a temperature of the hydrogen storage alloy 12 and generate hydrogen.

An H2 source temperature (Th2) may be determined to be constant by measuring the hydrogen pressure in advance to generate a desired hydrogen pressure (P). In this case, reproduction can be performed under simple conditions such as the power or current value of the heating element (hydrogen heater) 6. A non-evaporable getter material may be used as the hydrogen storage alloy 12. A cartridge heater or the like is used as the heating element (hydrogen heater) 6. The H2 source temperature (Th2) varies depending on a type and amount of the alloy, but is selected from a range of 200° C. to 700° C.

The same effect can also be obtained even when the heating element (hydrogen heater) 6 is in contact with the hydrogen storage alloy 12 in vacuum in the vacuum chamber 29 as shown in FIG. 4B. In this case, the interconnect 13 of the heating element (hydrogen heater) 6 is extracted to the outside of the vacuum chamber 29 by a feedthrough 14. As the hydrogen generating unit 3, the same effect can also be obtained even when a hydride of aluminum or magnesium may be used instead of the hydrogen storage alloy 12, and heating the hydride to generate hydrogen by thermal decomposition.

As another example of the hydrogen generating unit 3, as shown in FIG. 4C, a gas container 24 may be filled with a gas containing hydrogen and connected to the vacuum chamber 29 provided with the electron gun 15 via a vacuum pipe 16 separated by a hydrogen permeable film 25, and the hydrogen permeable film 25 may be heated by the heating element (hydrogen heater) 6. As the hydrogen permeable film 25, a metal such as Pd, Ta, Nb, or V is used. In this case, the H2 source temperature (Th2) is a heating temperature of the hydrogen permeable film 25 and is selected from a range of about 150° C. to 300° C.

In order to connect the vacuum pipe 16 to the vacuum chamber 29 in an ultra-high vacuum environment, the vacuum pipe 16 may be subjected to baking at about 200° C. for degassing before use. Since the hydrogen permeable film 25 often has high hydrogen permeability at about 200° C., when it is desired to control the gas pressure at a temperature higher than 200° C., and safety in a case of gas leakage is taken into consideration, the gas filled in the gas container 24, that diluted with an inert gas such as Ar tends to be used rather than 100% hydrogen. As for a degree of dilution, a volume of the inert gas is selected from, for example, about 10 to 10000 with respect to a volume of hydrogen of 1.

In the present embodiment, the linear motion feedthrough 17 causes the photocathode 1 to move to the position by the electric signal, and the motive power is based on a normal unit such as compressed air or a motor. Further, even if the position of the linear motion feedthrough 17 can be changed manually and the position of the photocathode 1 can be changed in response to an instruction of the GUI display of the display of the electron beam application device, the movement can be easily performed by an operator without requiring skill, and thus there is a same effect that an electron beam application device with good usability can be obtained.

The electron beam emitted from the photocathode 1 in the present embodiment has a high brightness and uniform energy, and contributes to a high resolution and a high speed measurement as an electron microscope. Further, when a short-pulse laser light source is used as the laser light source 22, a pulsed electron beam can be obtained without adding a component to an electron optical system, and thus the laser light source is useful for a measurement such as a time resolution. In the present embodiment, although hydrogen emission from the hydrogen generating unit 3 is controlled by the power of the heating element (hydrogen heater) 6 as shown in FIG. 2A, the same effect can also be obtained by monitoring a degree of vacuum in the vacuum chamber 29 in which the electron gun 15 is provided and controlling an amount of the current supplied to the heating element (hydrogen heater) 6 to make the degree of vacuum constant.

In the present embodiment, although the photocathode 1 is subjected to the surface cleaning at the surface cleaning position and the Cs-oxygen-based surface activation at the electron gun position, respectively, the surface activation may be performed at the surface cleaning position. Further, by disposing the elements such that the surface cleaning can be performed at the electron gun position, the linear motion feedthrough 17 for moving the photocathode 1 can be omitted.

According to the present embodiment, in the electron beam application device using a photoexcitation electron source using the photocathode as the electron gun, since the surface cleaning for preventing instability of the probe current can be automated, the electron gun with good usability can be used even by anyone, and the sample can be stably observed for a long time in the electron beam application device using the electron gun.

### Embodiment 2

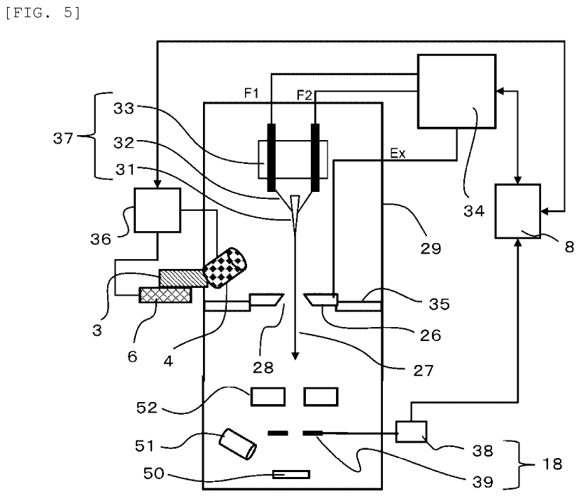

FIG. 5 is a schematic diagram of an electron beam application device using a needle shaped electron source according to Embodiment 2 of the invention. An FE electron source 37 is a field emission electron source that emits electrons by concentrating an electric field at a tip of a needle shaped metal 31, and has a structure in which the needle shaped metal 31 is mounted on a stem 33 via a filament 32. A typical W metal is used for the needle shaped metal 31. The stem 33 has two electrodes (F1, F2) using an insulator as a base, and is electrically connected to an electron source controller 34.

The extraction electrode 26 facing the FE electron source 37 is fixed to the vacuum chamber 29 by an insulator 35 and is electrically connected to the electron source controller 34. The vacuum chamber 29 accommodating the FE electron source 37 is maintained in an ultra-high vacuum range by a vacuum pump (not shown). Further, the atomic hydrogen generator 4, the hydrogen generating unit 3, the heating element (hydrogen heater) 6, and an atomic hydrogen controller 36 are provided as units for generating atomic hydrogen.

As a use method in the related art, the needle shaped metal 31 is heated to about 2000° C. or higher before the generation of the electron beam to remove oxides and carbides attached to the surface. For this purpose, a process of flashing is performed in which the electrodes (F1, F2) are instantaneously energized to set the filament 32 to a high temperature to heat the needle shaped metal 31. Next, the acceleration voltage (V0) is applied to each of the electrodes (F1, F2) and an extraction voltage is applied to the extraction electrode 26, and electrons emitted from the needle shaped metal 31 are guided to the electron optics column 30 as the electron beam probe 27 and used for observation of the sample 50.

When the hydrogen gas remaining in the vacuum chamber 29 is adsorbed on the surface of the needle shaped metal 31 and the value of probe current (Ip) of the electron beam probe 27 decreases, a process called mild flashing is performed in which power smaller than that in the flashing is instantaneously supplied between the electrodes (F1, F2) and the needle shaped metal 31 is set to a temperature of about 1000° C. or less to remove the hydrogen gas adsorbed on the surface. This time is a very short time of about 0.01 seconds to several seconds in order. Accordingly, the value of probe current (Ip) is recovered.

However, in the case of an operation for a longer period of time, for example, a gas containing carbon other than the hydrogen gas may intrude, and the adsorption on the surface cannot be removed by mild flashing, and a decrease in the value of probe current (Ip) and an increase in noise appear. In order to eliminate the occurrence, flashing by heating at a high temperature of about 2000° C. is performed, but since a movement of W atoms also occurs, a shape of the tip of the needle shaped metal 31 changes, and as a result, it is necessary to change the extraction voltage, change a condition setting in the electron optics column 30, and the like, which are bad in usability, and the shape change is not suitable for a long-term automatic measurement.

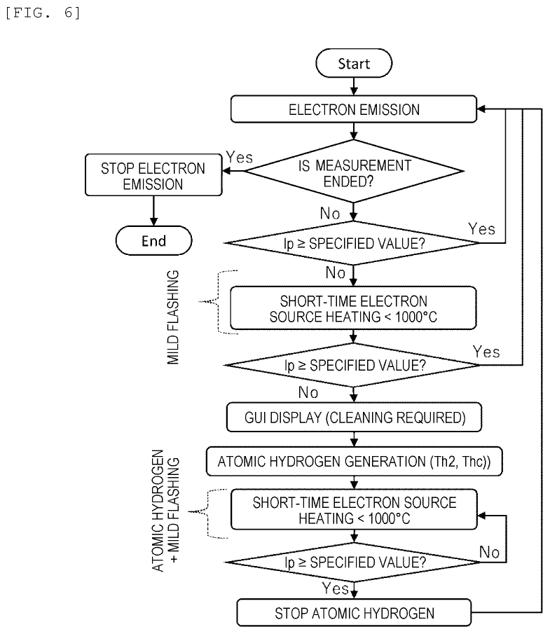

FIG. 6 is a flowchart of operations of the electron beam application device using the needle shaped electron source according to Embodiment 2 of the invention. In the present embodiment, the units for generating atomic hydrogen (3, 4, 6) and the atomic hydrogen controller 36 are provided, and the device is automatically operated in a high brightness state. FIG. 6 is an operation example after high-temperature flashing, and first, the electron emission is started and an SEM observation is performed. When the SEM observation is ended, the electron emission is stopped and ended. The end of the measurement is determined by a user or a system control device performing the automatic measurement. During the measurement in the SEM, the value of probe current (Ip) is monitored by the probe current measuring unit 18 at any time, and when the value of probe current (Ip) is equal to or more than a predetermined value, the measurement is continued as it is, when the value of probe current (Ip) is insufficient with respect to the predetermined value, the needle shaped metal 31 is heated to about 1000° C. or less in a short time, and when the value of probe current (Ip) is recovered, the electron emission is continued to continue the SEM observation. This is the same as a mild flashing process in the related art.

Here, when the value of probe current (Ip) does not recover, necessity of the surface cleaning (cleaning) is displayed, by the GUI display, on the display of the system control device 8 of the SEM, a signal is issued from the atomic hydrogen controller 36, the H2 source temperature (Th2) of the heating element (hydrogen heater) 6 of the hydrogen generating unit 3 and the HC heater temperature (Thc) of the W filament (HC heater) of the atomic hydrogen generator 4 are increased, and the atomic hydrogen is generated. Next, the filament 32 is set to a high temperature by instantaneous energization between the electrodes (F1, F2), and the needle shaped metal 31 is heated to about 1000° C. or less for a short time under the same conditions as in the mild flashing. This process is performed until the value of probe current (Ip) recovers to the predetermined value, and after the recovery, the energization to the heating element (hydrogen heater) 6 and the W filament (HC heater) of the atomic hydrogen generator 4 is stopped to stop the atomic hydrogen. Accordingly, the surface carbides are removed, and a tip surface of the needle shaped metal 31 is returned to an original state to continue the SEM observation.

In the present embodiment, the process of the surface cleaning with atomic hydrogen is performed during an SEM image observation, but in the case of highly accurate measurement in which noise or slight current fluctuation is desired to be avoided, the observation may be temporarily stopped as in Embodiment 1. Further, in the present embodiment, the cleaning is determined based on the decrease in the value of probe current (Ip), but there is an advantage that the cleaning can be further stabilized by adding a variation amount of the value of probe current (Ip), that is, an increase in noise to a determination item.

According to the present embodiment, in the electron beam application device using the needle shaped electron source as the electron gun, since the surface cleaning for preventing instability of the probe current can be automated, the electron gun with good usability can be used even by anyone, and the sample can be stably observed for a long time in the electron beam application device using the electron gun.

### Embodiment 3

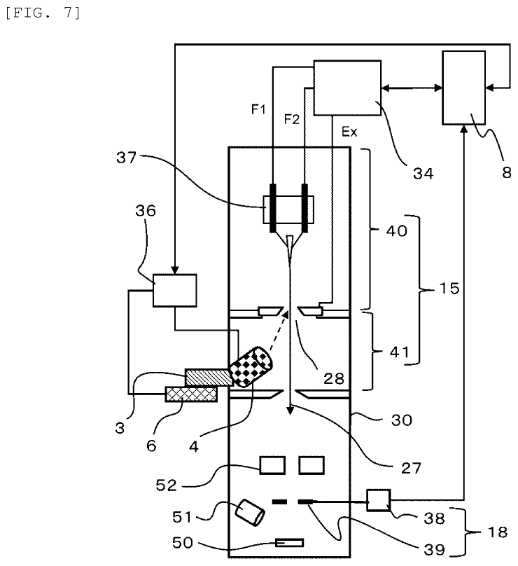

FIG. 7 is a schematic diagram of an electron beam application device using a needle shaped electron source according to Embodiment 3 of the invention. A difference from Embodiment 2 shown in FIG. 5 is that an electron source chamber 40 accommodating an electron source and a differential evacuation chamber 41 are provided as the configuration of the electron gun 15, atomic hydrogen is generated in the differential evacuation chamber 41, and the atomic hydrogen is supplied to the electron source chamber 40 via the aperture 28 between the electron source chamber 40 and the differential evacuation chamber 41.

As a control process of Embodiment 3, the same effect can also be obtained in the flow of FIG. 6 of Embodiment 2, but in the case of Embodiment 3, since the atomic hydrogen entering the electron source chamber 40 is greatly reduced as compared with the atomic hydrogen emitted from the atomic hydrogen generator 4, a supply amount of hydrogen may be increased. Alternatively, even when the atomic hydrogen is continuously generated for a long period of time, not instantaneously, and the FE electron source 37 is subjected to the mild flashing during that time, the adsorbed gas on the surface can be removed, and thus the stable value of probe current (Ip) for a long period of time can be also obtained. Further, it is possible to obtain an effect of preventing the noise of the value of probe current (Ip) as compared with the case where the FE electron source 37 is directly irradiated with the atomic hydrogen in the configuration as shown in FIG. 5 of Embodiment 2, and the effect of stabilizing the value of probe current (Ip) for a long period of time by restricting a hydrocarbon-based gas that causes contamination of the electron source from being adsorbed to or desorbed from surroundings and flowing into the electron source chamber 40.

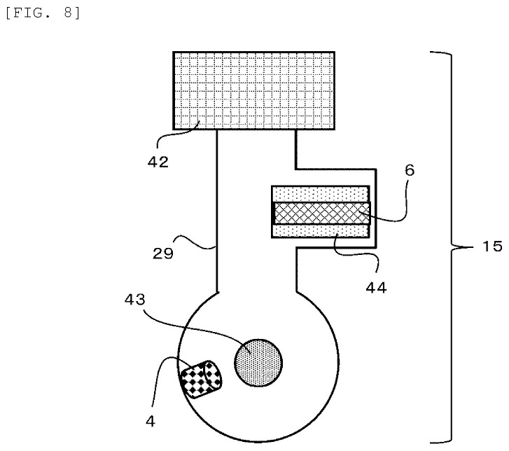

In Embodiments 1 to 3 described above, an example is shown in which the hydrogen generating unit 3 serving as a hydrogen generation source and the atomic hydrogen generator 4 are an integrated unit connected to each other, but the same effect can also be obtained when the both are separately disposed as long as hydrogen molecules are supplied to the atomic hydrogen generator 4. An example thereof is shown in FIG. 8. FIG. 8 is a schematic diagram of a cross-sectional structure of the electron gun 15 viewed from above. In the electron gun 15, an electron source part 43 is located in a center portion of the cylindrical container, and an ion pump 42 and a non-evaporable getter pump 44 for maintaining ultra-high vacuum are disposed in a peripheral portion of the vacuum chamber 29 to exhaust the gas. Here, the non-evaporable getter pump 44 is usually operated at room temperature, but generates hydrogen by being heated by the heating element (hydrogen heater) 6. The hydrogen spreads in the vacuum chamber 29 provided with the electron gun 15, and the atomic hydrogen is generated by the atomic hydrogen generator 4 separately placed near the electron source portion 43, and can be used for surface cleaning of the electron source, and the same effect as in Embodiments 1 to 3 can be obtained.

In addition, in Embodiments 1 to 3 described above, although a hydrogen cracking heater (HC heater) using the high-temperature W filament is used as the atomic hydrogen generator 4, the same effect can be obtained as long as unit for performing dissociation of hydrogen molecules is used, and for example, atomic hydrogen obtained by converting hydrogen gas into plasma and dissociating the plasma may be used. It is well known that the plasma can be generated by applying a high voltage or a high frequency, or being irradiated with a laser beam.

Further, in Embodiments 1, 2 described above, although the needle shaped metal 31 made of W is used as the FE electron source 37, other high-brightness electron sources are also sensitive to contamination on the surface, and thus the same effect can be obtained by applying the invention. For example, the same effect can be obtained by using a Schottky emission (SE) electron source in which Zr—O is adsorbed on a W (100) surface and heated, or a conductor having a high melting point such as a metal hexaboride or metal carbides, typically CeB6, as the needle shaped metal 31. In particular, when an FE electron source or an SE electron source is operated by constantly heating a needle shaped cathode, long-term stabilization is achieved by adjusting the value of probe current (Ip) so as to intermittently or continuously generate atomic hydrogen.

### REFERENCE SIGNS LIST

1: photocathode
2: cathode heater
3: hydrogen generating unit
4: atomic hydrogen generator
5: oxygen generating unit
6: heating element (hydrogen heater)
7: surface controller
8: system control device
9: Cs source
10: photoelectric film
11: transparent substrate
12: hydrogen storage alloy
13: interconnect
14: feedthrough
15: electron gun
16: vacuum pipe
17: linear motion feedthrough
18: probe current measuring unit
19: electron gun controller
20: condensing lens
21: excitation light
22: laser light source
23: window
24: gas container
25: hydrogen permeable film
26: extraction electrode
27: electron beam probe
28: aperture
29: vacuum chamber
30: electron optics column
31: needle shaped metal
32: filament
33: stem
34: electron source controller
35: insulator
36: atomic hydrogen controller
37: FE electron source
38: current detector
39: aperture
40: electron source chamber
41: differential evacuation chamber
42: ion pump
43: electron source part
44: non-evaporable getter pump
50: sample
51: secondary electron detector
52: electron optics part

1. An electron beam application device comprising:
a photocathode including a photoelectric film;
a cathode heater configured to heat the photocathode;
an atomic hydrogen generating unit configured to perform dissociation of hydrogen molecules to generate atomic hydrogen;
a control unit configured to control surface cleaning of a surface of the photoelectric film; and
a measurement unit configured to measure a value of probe of an electron beam probe emitted from the photocathode, wherein
when the value of probe measured by the measurement unit falls below a predetermined value, the control unit determines a surface cleaning condition of the photoelectric film, and controls the cathode heater and the atomic hydrogen generating unit under the determined surface cleaning condition to perform the surface cleaning on the surface of the photoelectric film.

2. The electron beam application device according to claim 1, wherein
the control unit determines the surface cleaning condition of the photoelectric film based on a history of the value of probe measured by the measurement unit.

3. The electron beam application device according to claim 2, further comprising:
a hydrogen generating unit configured to generate hydrogen molecules; and
a hydrogen heater configured to heat the hydrogen generating unit, wherein
the control unit controls the hydrogen heater under the determined surface cleaning condition.

4. The electron beam application device according to claim 2, further comprising:
a display, wherein
before performing the surface cleaning on the surface of the photoelectric film, the display displays, by GUI display, that the surface cleaning is required.

5. The electron beam application device according to claim 2, comprising:
an electron source chamber accommodating the photocathode; and
a differential evacuation chamber, wherein
the atomic hydrogen generating unit is provided in the differential evacuation chamber, and
the atomic hydrogen is supplied to the electron source chamber through an aperture between the electron source chamber and the differential evacuation chamber.

6. The electron beam application device according to claim 2, further comprising:
a Cs source, wherein
the surface cleaning on the surface of the photoelectric film is performed when the value of probe measured by the measurement unit does not recover to the predetermined value or more even if Cs is added by the Cs source.

7. The electron beam application device according to claim 3, wherein
the atomic hydrogen generating unit and the hydrogen generating unit are provided separately, and the atomic hydrogen generating unit is provided near the photocathode.

8. An electron beam application device comprising:
a needle shaped metal;
a filament configured to heat the needle shaped metal;
an atomic hydrogen generating unit configured to perform dissociation of hydrogen molecules to generate atomic hydrogen;
a control unit configured to control surface cleaning of a surface of the needle shaped metal; and
a measurement unit configured to measure a value of probe of an electron beam probe emitted from the needle shaped metal, wherein
when the value of probe measured by the measurement unit falls below a predetermined value, the control unit determines a surface cleaning condition of the needle shaped metal, and controls the filament and the atomic hydrogen generating unit under the determined surface cleaning condition to perform the surface cleaning on the surface of the needle shaped metal.

9. The electron beam application device according to claim 8, wherein
the control unit determines the surface cleaning condition of the needle shaped metal based on a history of the value of probe measured by the measurement unit.

10. The electron beam application device according to claim 9, further comprising:
a hydrogen generating unit configured to generate hydrogen molecules; and
a hydrogen heater configured to heat the hydrogen generating unit, wherein
the control unit controls the hydrogen heater under the determined surface cleaning condition.

11. The electron beam application device according to claim 9, further comprising:
a display, wherein
before performing the surface cleaning on the surface of the needle shaped metal, the display displays, by GUI display, that the surface cleaning is required.

12. The electron beam application device according to claim 9, comprising:
an electron source chamber accommodating the needle shaped metal; and
a differential evacuation chamber, wherein
the atomic hydrogen generating unit is provided in the differential evacuation chamber, and
the atomic hydrogen is supplied to the electron source chamber through an aperture between the electron source chamber and the differential evacuation chamber.

13. The electron beam application device according to claim 10, wherein
the atomic hydrogen generating unit and the hydrogen generating unit are provided separately, and the atomic hydrogen generating unit is provided near the needle shaped metal.
